(19) United States
(12) Patent Application Publication
(10) Pub. No.: US 2011/0240107 A1
(43) Pub. Date: Oct. 6, 2011

(54) LARGE-AREA THIN-FILM-SILICON PHOTOVOLTAIC MODULES

(75) Inventors: Johannes Meier, Corcelles (CH); Stefano Benagli, Neuchatel (CH); Julien Bailat, Glovelier (CH); Daniel Borrello, Cortaillod (CH); Jerome Steinhauser, Neuchatel (CH); Jochen Hötzel, Kreuzlingen (CH); Lucie Castens, Neuchatel (CH); Jean-Baptiste Orhan, La Chaux-de-Fonds (CH); Yassine Djeridane, Neuchatel (CH); Evelyne Vallat-Sauvain, Chezard-St. Martin (CH); Ulrich Kroll, Corcelles (CH)

(73) Assignee: OERLIKON SOLAR AG, TRUBBACH, Trubbach (CH)

(21) Appl. No.: 13/079,072

(22) Filed: Apr. 4, 2011

Related U.S. Application Data
(60) Provisional application No. 61/320,803, filed on Apr. 5, 2010.

(51) Int. Cl. H01L 31/06

(52) U.S. Cl. 136/255

(57) ABSTRACT

Micromorph tandem cells with stabilized efficiencies of 11.0% have been achieved on as-grown LPCVD ZnO front TCO at bottom cell thickness of just 1.3 μm in combination with an antireflection concept. Applying an advanced LPCVD ZnO front TCO stabilized tandem cells of 10.6% have been realized at a bottom cell thickness of only 0.8 μm. Implementing intermediate reflectors in Micromorph tandem cell devices allow for, compared to commercial SnO₂, reduced optical losses when LPCVD ZnO is used. At present highest stabilized cell efficiency reached 11.3% incorporating an in-situ intermediate reflector with a bottom cell thickness of 1.6 μm.

### BACKGROUND OF THE INVENTION

FIG. 9 shows a tandem-junction silicon thin film solar cell as known in the art. Such a thin-film solar cell 50 usually includes a first or front electrode 42, one or more semiconductor thin-film p-i-n junctions (52-54, 51, 44-46, 43), and a second or back electrode 47, which are successively stacked on a substrate 41. Each p-i-n junction 51, 43 or thin-film photoelectric conversion unit includes an i-type layer 53, 45 sandwiched between a p-type layer 52, 44 and an n-type layer 54, 46 (p-type=positively doped, n-type=negatively doped). Substantially intrinsic in this context is understood as undoped or exhibiting essentially no resultant doping. Photoelectric conversion occurs primarily in this i-type layer; it is therefore also called absorber layer. The TCO front and back electrodes or electrode layers contact layers 42, 47 can be made of zinc oxide, tin oxide, ITO or alike. A reflector 48 is usually applied after the back contact for reflecting not yet absorbed light back into the active layers; it can be a diffuse white reflector or a metallic one (Ag, Al). A tandem-junction silicon solar cell is hereinafter called Micromorph cell, if a top cell 51 with an a-Si i-layer 53 is combined with a bottom cell 43 including an i-layer 45 of μc-Si:H.

On the way towards achieving grid parity, thin film silicon solar modules offer a significant potential for reducing manufacturing costs. The challenge of amorphous and microcrystalline silicon based technology is the improvement of module performance compared to crystalline technology. While nowadays current manufacturing lines based on amorphous and microcrystalline silicon are in operation, the need for higher efficiencies is of major interest besides cost reduction. Considerable efforts have been focused on improved device efficiencies. Her it is reported on the status of amorphous p-i-n single-junction and Micromorph tandems cells using industrial PECVD KAI equipment and LPCVD (Low Pressure Chemical Vapor Deposition) ZnO as TCO technology (respective manufacturing systems available from Oerlikon Solar AG, Trübbach, Switzerland). As light-trapping is one of the keys to improve performance, special care on the development of LPCVD ZnO tailored to amorphous or Micromorph tandem solar cells have been taken. In addition Oerlikon has developed an in-house AR concept that allows further reducing the losses of light coupling into the absorber.

### EXPERIMENT

To improve deposition rates for solar device-quality amorphous and especially microcrystalline silicon, flat panel display-type reactors (commercially available type KAI by Oerlikon Solar AG) were adapted to run at a higher excitation frequency of 40.68 MHz. For the experiments described herein results were obtained in KAI-M (520×410 mm²) reactors.

In order to improve light-trapping, the tuning of the LPCVD front ZnO contact layer for optimized a-Si:H single-junction, respectively Micromorph tandem solar cells was in the focus. Therefore, different types of front TCO's (as-grown type-A, and type-B, Haze over 40% at 600 nm) have been developed and adjusted for very efficient light-scattering. In addition an in-house AR (Anti-Reflecting) concept has been found that allows for further enhanced light coupling into the device.

Recently an intermediate reflector concept based on PECVD processes in combination with commercial SnO₂ as front TCO has been developed. This however leads to remarkable optical losses in the microcrystalline silicon bottom cell. Consequently intermediate reflectors have been implemented in Micromorph tandems on LPCVD ZnO improving every interface and taking into account the advantage of the enhanced optical light-management of this type of front TCO.

ZnO back contacts in combination with a white reflector reveal excellent light-trapping properties and have been systematically applied in all cells presented here. The test cells were laser scribed to areas of well-defined 1 cm². Mini-modules were patterned by laser-scribing to monolithic series connection.

In order to evaluate the stabilized performance the tandem cells were light-soaked at 50° C. under 1 sun illumination for 1000 hours. The devices were characterized under AM 1.5 illumination delivered from double-source sun simulators. Spectral data of transmission were analyzed by a Perkin-Elmer lambda 950 spectrometer.

### SHORT DESCRIPTION OF THE FIGURES

FIG. 1: Left: Total and diffuse transmission of LPCVD ZnO of type-A on a Schott Borofloat 33 glass substrate. Right: Enlarged surface of the as-grown ZnO with Haze of about 12%.

Table 1 shows an overview of cells prepared and measured by Oerlikon Solar-Lab Neuchâtel and independently characterized by NREL.

FIG. 2: NREL I(V) plot of the stabilized record efficiency of 10.09±0.3% for a a-Si:H single-junction solar cell.

FIG. 3: Absolute External Quantum Efficiency deduced from the relative QE of NREL and the short-circuit current density under AM1.5 measured at NREL for the record cell #3497.

FIG. 4: AM1.5 I-V characteristics by ESTI laboratories of JRC in Ispra of the best p-i-n a-Si:H (light-soaked) 10×10 cm² mini-module on LPCVD-ZnO type A. The intrinsic a-Si:H absorber has a thickness of only 180 nm.

FIG. 5: Micromorph tandem cells AM1.5 characteristics developed on type-A ZnO in the initial and light-soaked state.

FIG. 6: QE of Micromorph tandem cells on type-A & -B front ZnOs

FIG. 7: Micromorph tandem cell in the initial and light-soaked state on type-B front ZnO with pc-Si:H layer thickness of only 0.8 μm.

FIG. 8: Micromorph tandem cell in the initial and fully light-soaked state with incorporated intermediate reflector using type-A ZnO as front TCO.

FIG. 9: Prior Art configuration of a micromorph tandem junction solar cell.

### RESULTS

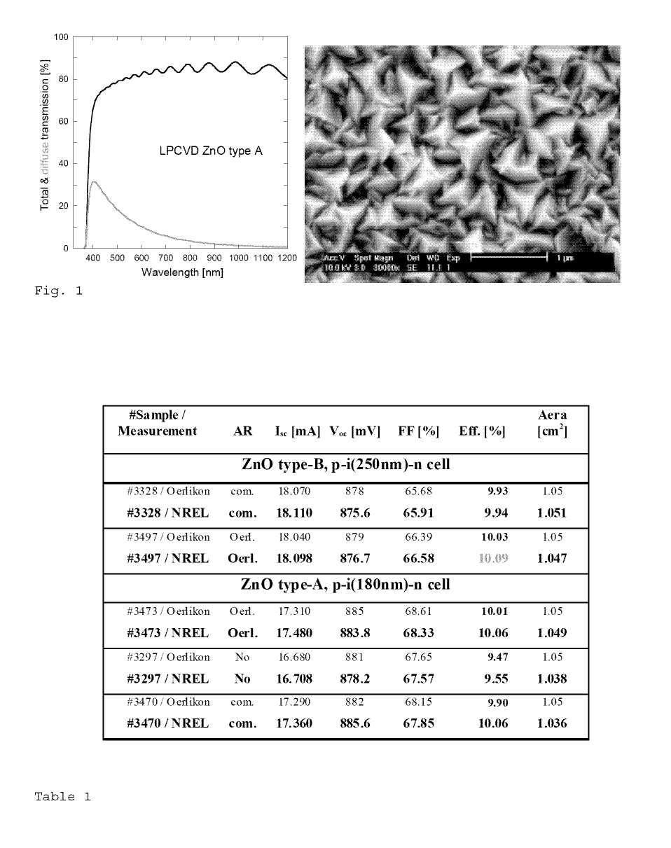

The (ZnO) front contact layer 42 has been developed in a LPCVD reactor system resulting in improved optical transmission characteristics as shown in FIG. 1. This ZnO film represents type-A material, whereas a different type-B ZnO is differently processed to achieve very high Haze of −40%. FIG. 1 shows on the left total and diffuse transmission of LPCVD ZnO of type-A on a Schott Borofloat 33 glass substrate. Right figure: As grown Zno, enlarged. Haze of type-A ZnO is about 12%.

In previous studies the influence of thickness of the intrinsic a-Si:H absorber layer (FIG. 9, detail 53) on the initial and stabilized efficiencies has carefully been investigated especially for SnO₂ and LPCVD ZnO. Whereas for commercially available SnO₂ the properties of the TCO are fixed and determined by the supplier, a LPCVD process as used herein allows a further improvement with respect to the optical and structural features of the front TCO (FIG. 9, detail 42). Thus, tuning both the PECVD cell deposition and the front TCO opens a new window for high efficient amorphous cells at rather thin intrinsic absorbers. Thus, we achieved stabilized cell efficiencies in several runs and on two different types of TCO over the 10% barrier. In order to verify our own measurements we sent the cells immediately after light-soaking also to NREL. The comparison between our cells characterization and those of NREL are given in Tab. 1.

Table 1 shows an overview of cells prepared and measured by the inventors and independently characterized by NREL. All cells with LPCVD-ZnO front and back contacts were deposited in a R&D single-chamber KAI-M PECVD system and are light-soaked (1000h, one sun light intensity, 50° C. and in Voc-conditions). Whereas cells #3328 and #3470 have commercial AR coating, on cells #3497 and #3473 an in-house AR (antireflection layer) was applied. Between both measurements is a time gap of about 9 days due to transport.

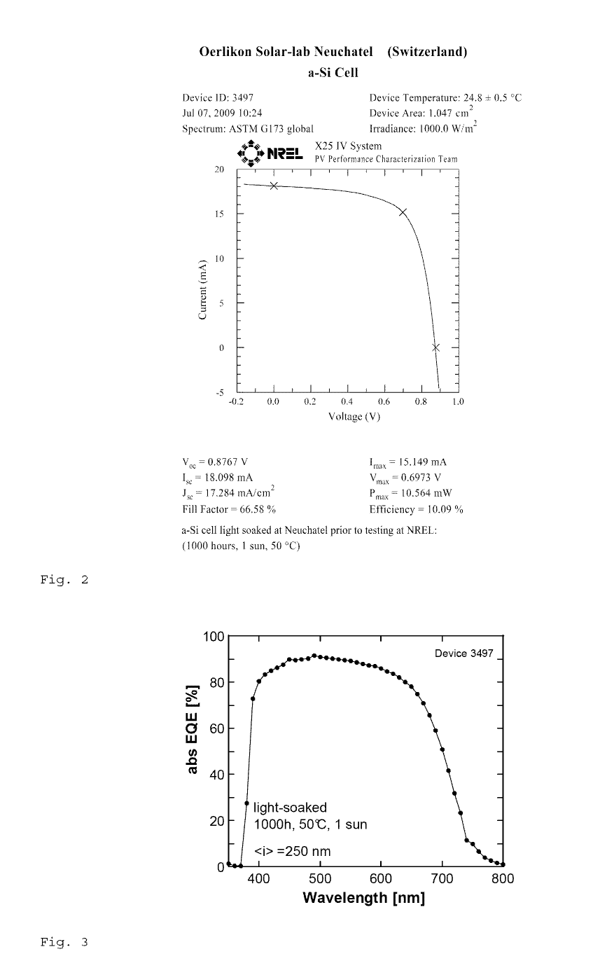

The record cell #3497 (a-Si:H single junction) measured by NREL is further detailed in FIG. 2. The remarkably high stabilized efficiency of 10.09±0.3% has been confirmed. It is the first time an amorphous silicon single-junction cell reaches a stabilized efficiency beyond the 10% barrier. Compared to the previous record (η=9.47±0.3% obtained by IMT Neuchatel) a significant improvement of 0.6% absolute could be attained. The i-layer thickness of this cell is 250 nm. The used substrate is a 1 mm Schott Borofloat 33 glass on which LPCVD-ZnO with high Haze factor (ZnO type-B) was deposited. On this cell our in-house AR was applied as well.

The absolute external QE characteristics of these cells are remarkably high. FIG. 3 represents the data deduced from the NREL measurements. Even in the light-soaked state the cells reach 90% QE and 80% at short wavelength of 400 nm. This result could finally be attained thanks to an optimization of all involved layers and interfaces forming the cell. In particular, apart of the high quality and standard band gap i-layer (deposited in the single-chamber KAI reactor) the excellent optical and light-scattering properties of LPCVD-ZnO are one of the main key elements for the enhanced performance.

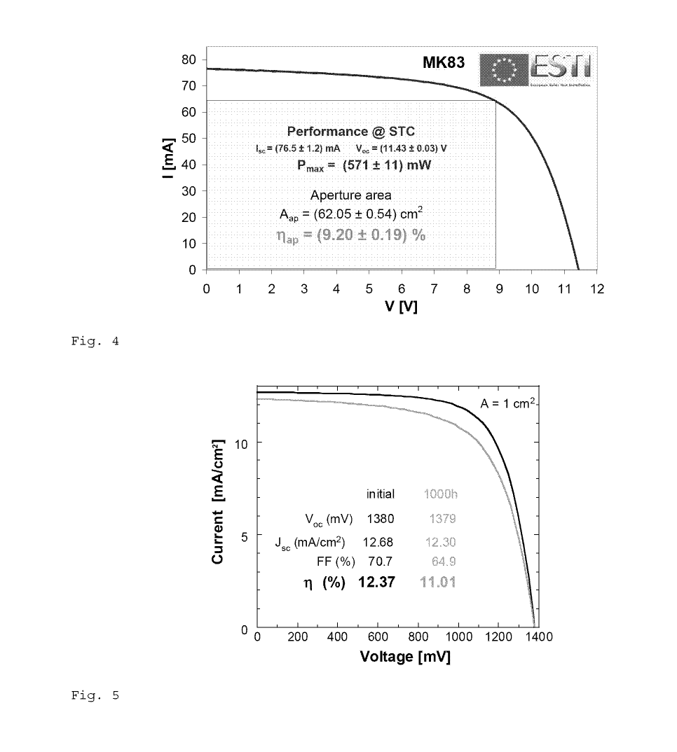

The 10.09% stabilized cell is a remarkable new result for amorphous silicon technology, however, the cells achieving 10.06% at an i-layer thickness of 180 nm only is even more striking. Thus, the 10.06% cell on type-A ZnO is very close to present industrialized mass processes, however, at remarkable reduce cell device thickness which allows for further reduction of fabrication cost. In order to test the up-scaling, the cells of type #3473 & #3470 on ZnO-A have been implemented in 10×10 cm² mini-modules applying laser-patterning for the monolithic series connection. As well the mini-modules were fully light-soaked and sent then to ESTI of JRC Ispra for independent characterization. FIG. 4 reflects the (stabilized) module aperture efficiency of 9.20±0.19% as certified. The ESTI characteristics of the record mini-module is in excellent agreement within the given measurement errors with the NREL measurements of the same type of device (#3473 & #3470) taking typical up-scaling losses into account. In fact thin film module efficiencies are mainly reduced due to area losses in laser-patterning (at least 3% in this case) and series resistance losses due to the front TCO.

### EMBODIMENT 1

### Micromorph Tandem Cells on ZnO Type-A Substrates

Micromorph tandem cells have been prepared in various ranges of top & bottom cell thickness configurations with respect to the potential for highest stabilized efficiency. In addition, a range of configurations of Micromorph tandem cells have been prepared including the a. m. in-house AR. In FIG. 5 the present highest stabilized test cell efficiency together with its initial characteristics are given. The cell reaches an initial efficiency well above 12% with rather high short-circuit current densities of 12.6 mA/cm² thanks to a very efficient light-trapping as the bottom cell is only 1.3 μm thick. The relative degradation is about 11% and is consistent with the extrapolated degradation rate of the amorphous silicon top cell.

FIG. 5 shows a Micromorph tandem cell's AM1.5 characteristics developed on type-A ZnO in the initial and light-soaked state (1000h, 1 sun, 50° C.) applying the a.m. AR concept. The pc-Si:H bottom cell has thickness of only 1.3 μm.

### EMBODIMENT 2

### Micromorph Tandem Cells on ZnO Type-B Substrates

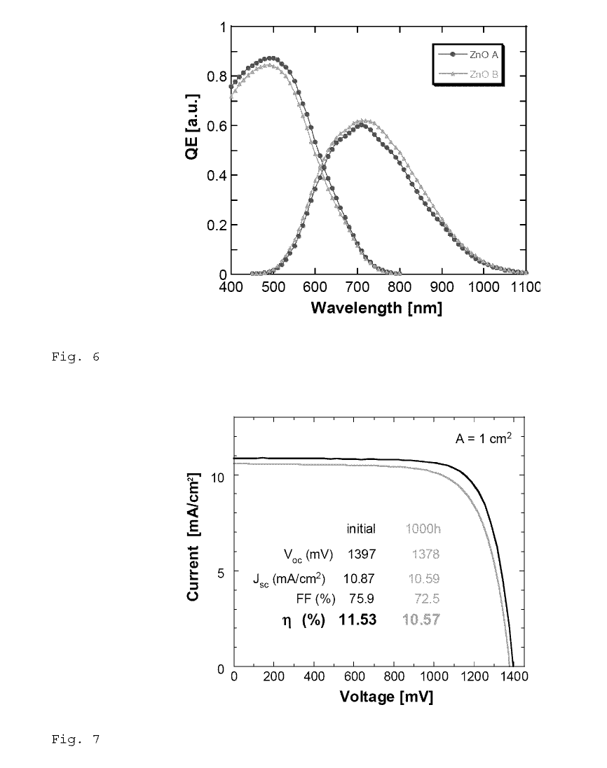

The effect of the enhanced Haze of ZnO type-B is compared with ZnO type-A in FIG. 6 by the quantum efficiency (QE) of Micromorph tandem cells with similar top and identical bottom cell thicknesses. The enhanced light-trapping capability of ZnO type-B leads to remarkable enhancement in the bottom cell current. FIG. 6 shows the QE of Micromorph tandem cells on type-A & -B front ZnOs. The bottom cells have a thickness of 1.2 μm, top cells have comparable thicknesses.

### EMBODIMENT 3

Micromorph tandem cells have been prepared on ZnO B front TCO. Due to the very efficient light-trapping of the pc-Si:H bottom cell, the microcrystalline silicon intrinsic absorber layer thickness could remarkably be reduced. In FIG. 7 the AM1.5 I-V characteristics of a tandem cell with a microcrystalline bottom cell of only 0.8 μm is shown in the initial and light-soaked state. The 10.6% stabilized efficiency is a remarkable result as the total silicon absorber layer top & bottom cell is only about 1 μm thick. Regarding manufacturing cost this very thin but efficient device represents a very interesting option. FIG. 7 shows said results of a Micromorph tandem cell in the initial and light-soaked state on type-B front ZnO with pc-Si:H layer thickness of only 0.8 μm. The relative degradation achieved is 8.3%.

### EMBODIMENT 4

### Intermediate Reflectors in Micromorph Tandems

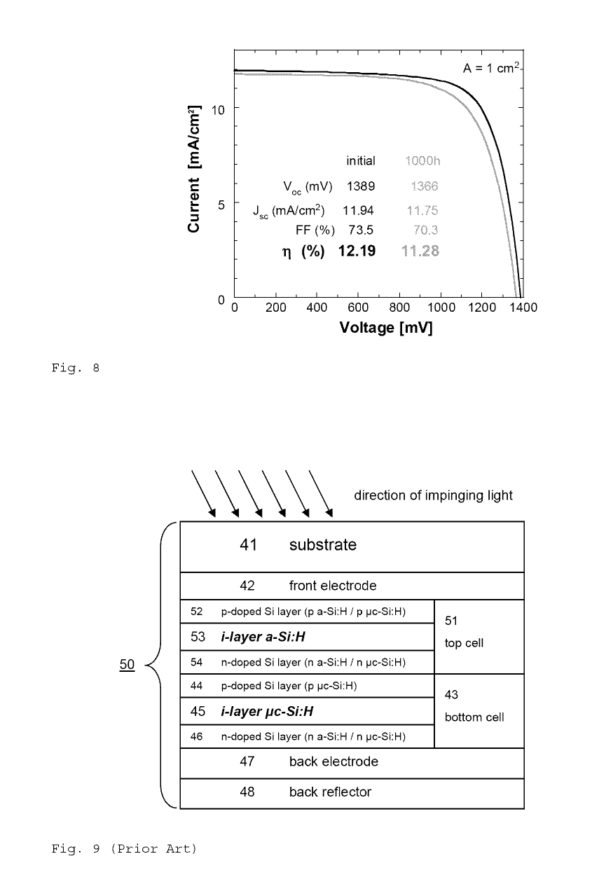

Intermediate reflectors based on silicon have been developed in KAIM reactors to enhance the light-trapping in the amorphous silicon top cell. Refractive indexes of down to 1.68 could be prepared for these layers in Prior Art. Such intermediate reflectors have been implemented in Micromorph tandem cells and studied for LPCVD ZnO and SnO₂ as front TCO windows with respect to its spectral reflection properties. The comparison indicates directly a more pronounced loss in case of SnO₂ front contacts whereas for LPCVD ZnO the implementation of the intermediate reflector seems to barely affect optical losses. The high current potential and the reduced loss mechanism in case of ZnO motivated to further improve the device with intermediate layer incorporated. FIG. 8 captures the highest stabilized test cell device of 11.3% efficiency so far. This cell is deposited on type-A front ZnO and has a top cell thickness of 160 nm combined with a bottom cell of only 1.6 μm.

It is noted that type-A front ZnO is based on a simple LPCVD process as it is industrially already applied in mass production. Thus, at present the highest stabilized Micromorph tandem cell is achieved with an intermediate reflector and at a rather low bottom cell thickness of 1.6 μm, much thinner than one would require for SnO₂ to get the same short-circuit current level. FIG. 8 shows a Micromorph tandem cell in the initial and fully light-soaked state with incorporated intermediate reflector using type-A ZnO as front TCO. The top cell has a thickness of 160 nm whereas the bottom cell one of 1.6 μm. The cell carries our in-house developed AR. Note the relative degradation is only 8%.

### CONCLUSIONS

Excellent properties of in-house developed LPCVD-ZnO films in combination with high quality of the silicon layers deposited in a single-chamber KAI PECVD reactor have demonstrated to be very important in achieving high efficiency levels. ZnO layers with high transmission, high conductivity, excellent light-scattering capabilities and a surface morphology allow for the growth of high quality a-Si:H solar cell devices. A record stabilized cell efficiency of 10.09±0.3% on 1 cm² could be attained and independently confirmed by NREL. The 180 nm a-Si:H p-i-n cell process has been transferred to mini-modules of 10×10 cm² using the monolithic series connection by laser patterning. Measurements at ESTI laboratories of JRC in Ispra on light-soaked mini-modules confirmed a module aperture area efficiency of 9.20±0.19%. This high stabilized module efficiency is coherent with the NREL cell efficiency measurements, as modules efficiencies are reduced due to scribe and series resistance losses. Micromorph tandem cells have been successfully optimized on in-house ZnO at rather thin pc-Si:H bottom cell thickness. On standard as-grown type-A ZnO stabilized efficiencies of 11.0% have been obtained with a microcrystalline bottom cell of only 1.3 μm thickness. On advanced front ZnO substrates stabilized efficiencies of 10.6% have been reached using a bottom cell of just 0.8 μm thickness. Applying an intermediate reflector in Micromorph tandems reveal more favorable light-trapping characteristics for LPCVD ZnO as front contact compared to commercial SnO₂ shown by a reduced spectral reflection loss. Based on this advantage Micromorph tandem cells of 11.3% stabilized efficiencies with incorporated intermediate reflector have been attainted on LPCVD ZnO. Hereby the bottom cell has a thickness of only 1.6 μm.

1. Thin-film tandem junction silicon solar cell comprising
a substrate (41);
a front electrode (42);
a top cell (51) including an amorphous silicon i-layer;
a bottom cell (43) including a microcrystalline silicon i-layer;
a back electrode (47) and a back reflector (48)
characterized in that
the front electrode comprises ZnO with a haze of 12%,
the bottom cell (43) is essentially 1.3 μm thick and
the stabilized efficiency after 1000h light soaking (AM1.5) is above 11%

2. Thin-film tandem junction silicon solar cell comprising
a substrate (41);
a front electrode (42);
a top cell (51) including an amorphous silicon i-layer;
a bottom cell (43) including a microcrystalline silicon i-layer;
a back electrode (47) and a back reflector (48)
characterized in that
the front electrode comprises ZnO with a haze of 40%, the bottom cell (43) is essentially 0.8 μm thick, the added thickness of both i-layers (53,45) is about 1 μm,
the stabilized efficiency after 1000h light soaking (AM1.5) is above 10.5%

3. Thin-film tandem junction silicon solar cell comprising
a substrate (41);
a front electrode (42);
a top cell (51) including an amorphous silicon i-layer;
a bottom cell (43) including a microcrystalline silicon i-layer;
a back electrode (47) and a back reflector (48)
an intermediate reflector arranged between top cell (51) and bottom cell (43) exhibiting a refractive index of 1.68
characterized in that
the front electrode comprises ZnO with a haze of 12%,
the bottom cell (43) is essentially 1.6 μm thick,
the top cell (51) is essentially 160 nm thick and the stabilized efficiency after 1000h light soaking (AM1.5) is above 11%.
